(19) United States
(12) Patent Application Publication
(10) Pub. No.: US 2016/0086722 A1
(43) Pub. Date: Mar. 24, 2016

(54) COMMON MODE FILTER AND METHOD OF MANUFACTURING THE SAME

(71) Applicant: SAMSUNG ELECTRO-MECHANICS CO., LTD., Suwon-Si (KR)

(72) Inventors: Won Chul SIM, Suwon-Si (KR); Dong Hwan LEE, Suwon-Si (KR); Kwang Mo KIM, Suwon-Si (KR)

(21) Appl. No.: 14/854,007

(22) Filed: Sep. 14, 2015

(30) Foreign Application Priority Data
Sep. 19, 2014 (KR) 10-2014-0124956

(51) Int. Cl. H01F 27/28; H03H 7/01; H01F 41/04; H01F 27/29

(52) U.S. Cl. CPC H01F 27/2804; H01F 27/29; H03H 7/01; H01F 41/041; H01F 2027/2809

(57) ABSTRACT

Disclosed herein is a common mode filter in order to improve attenuation of the common mode filter, the common mode filter including: a support substrate; an insulation layer provided on the support substrate and including a coil pattern formed therein; and a non-magnetic dielectric body provided on the insulation layer.

### CROSS REFERENCE(S) TO RELATED APPLICATIONS

This application claims the benefit under 35 U.S.C. Section [120, 119, 119(e)] of Korean Patent Application Serial No. 10-2014-0124956, entitled “Common Mode Filter and Method of Manufacturing the Same” filed on Sep. 19, 2014, which is hereby incorporated by reference in its entirety into this application.

### BACKGROUND OF THE INVENTION

1. Technical Field

The present disclosure relates to a common mode filter, and more particularly, to a common mode filter of which attenuation is improved.

2. Description of the Related Art

In accordance with the development of a technology, electronic devices such as a portable phone, a home appliance, a personal computer (PC), a personal digital assistant (PDA), a liquid crystal display (LCD), and the like, have been changed from an analog scheme into a digital scheme and a speed of the electronic devices has increased due to an increase in an amount of processed data. Therefore, a universal serial bus (USB) 2.0, a USB 3.0, and a high-definition multimedia interface (HDMI) have been widely spread as a high-speed signal transmitting interface and have been used in many digital devices such as a personal computer and a digital high-definition television.

These high-speed interfaces adopt a differential signal system transmitting differential signals (differential mode signals) using a pair of signal lines unlike a single-end transmitting system that has been generally used for a long period of time. However, electronic devices that are digitized and have an increased speed are sensitive to stimulus from the outside, such that signal distortion by high frequency noise has been frequently generated.

In order to remove this noise, a filter has been installed in the electronic devices, and particularly, a common mode filter for removing common mode noise has been widely used in a high speed differential signal line, or the like. The common mode noise indicates noise generated in the differential signal line, and the common mode filter removes common noise that may not be removed by an existing filter.

Meanwhile, recently, as a frequency used in the electronic devices has gradually increased, a common mode filter of which narrow band characteristics and attenuation are improved at a high frequency band has been required. That is, a narrow band of about ±25% to ±20% based on common impedance of 90Ω, and high attenuation of −30 bB or more at a band of several Ghz have been required.

However, in the case of a common mode filter according to the related art, using a ferrite-based magnetic material, due to characteristics of the magnetic material, as the frequency is increased to a band of Ghz, magnetic permeability has been rapidly decreased, and on the contrary, a magnetic loss (Tan δ) has been increased, such that attenuation of the common mode filter according to the related art has been essentially decreased at a high frequency band.

### SUMMARY OF THE INVENTION

An object of the present disclosure is to provide a common mode filter capable of decreasing a magnetic loss at a high frequency band of Ghz to improve attenuation of noise.

According to an exemplary embodiment of the present disclosure, there is provided a common mode filter capable of preventing a decrease in attenuation by a magnetic loss even though a magnetic flux generated in a the coil pattern at the time of applying current passes through a non-magnetic dielectric body, by disposing the non-magnetic dielectric body on an insulation layer in which the coil pattern is formed.

According to the present disclosure, there is provided a common mode filter of which production efficiency may be improved by using as any one selected from the group consisting of an epoxy resin, a phenol resin, a urethane resin, a silicone resin, and a polyimide resin, or a mixture thereof as a material configuring non-magnetic dielectric layer, and particularly, using the same material as that of the insulation material among these materials.

According to the present disclosure, there is provided a common mode filter in which a support substrate is disposed at a low portion thereof, and the insulation layer and the non-magnetic dielectric body are formed. Here, a common mode filter of which attenuation is further improved may be provided by forming the support substrate using a magnetic material such as Ni-based ferrite, Ni—Zn-based ferrite, Ni—Zn—Cu-based ferrite, or the like, or a non-magnetic material such as alumina, silica, titanium oxide, or the like.

According to another exemplary embodiment of the present disclosure, there is provided a method of manufacturing a common mode filter including: preparing a support substrate; forming an insulation layer in which a coil pattern is formed on the support substrate; and forming a non-magnetic dielectric body on the insulation layer.

Here, the non-magnetic dielectric body may be formed by filling a non-magnetic paste prepared from a composition containing a polymer resin such as epoxy, silicon, polyimide, or the like, and heat-treating the non-magnetic paste. In the method of manufacturing a common mode filter, as the polymer resin contained in the composition of the non-magnetic paste, the same material as the polymer resin configuring the insulation layer may be used in order to increase production efficiency.

### BRIEF DESCRIPTION OF THE DRAWINGS

FIG. 1 is a perspective diagram of a common mode filter according to an exemplary embodiment of the present disclosure.

FIG. 2 is a cross-sectional diagram taken along line I-I′ of FIG. 1.

FIG. 3 is a cross-sectional diagram taken along line II-II′ of FIG. 1.

FIG. 4 is a plan diagram of a layer provided with a coil pattern according to the present disclosure.

FIG. 5 is an equivalent circuit diagram of a common mode filter according to the related art, including a resistor.

FIG. 6 is a graph illustrating frequency-dependent attenuation of the common mode filter according to the related art.

FIG. 7 is a graph for comparing attenuation of the common mode filter according to the present disclosure and attenuation of the common mode filter according to the related art with each other.

FIG. 8 is a cross-sectional diagram of a common mode filter according to another exemplary embodiment of the present disclosure.

FIG. 9 is a flow chart sequentially illustrating a method of manufacturing a common mode filter according to the present disclosure.

### DESCRIPTION OF THE PREFERRED EMBODIMENTS

Various advantages and features of the present disclosure and methods accomplishing them will become apparent from the following description of exemplary embodiments with reference to the accompanying drawings. However, the present disclosure is limited to exemplary embodiments set forth herein, but may be modified in many different forms. These exemplary embodiments may be provided so that the scope of the present disclosure will be thorough and complete, and will fully convey the scope of the disclosure to those skilled in the art to which the present disclosure pertains.

Terms used in the present specification are for explaining exemplary embodiments rather than limiting the present disclosure. Unless explicitly described to the contrary, a singular form includes a plural form in the present specification. In addition, constituents, steps, operations and/or elements stated in this specification do not exclude any other constituents, steps, operations and/or elements.

meanwhile, the components shown in the drawings are not necessarily drawn according to the reduced scale. For example, in order to help the understanding of the present disclosure, some components shown in the drawings may be exaggerated as compared with other components. In addition, the same reference numbers will indicate the same component throughout the drawings, for simplification and clearness of illustration, a general configuration scheme will be shown in the accompanying drawings, and a detailed description of the feature and the technology well known in the art will be omitted in order to prevent a discussion of exemplary embodiments of the present disclosure from being unnecessarily obscure.

Hereinafter, a configuration and an acting effect of exemplary embodiments of the present disclosure will be described in more detail with reference to the accompanying drawings.

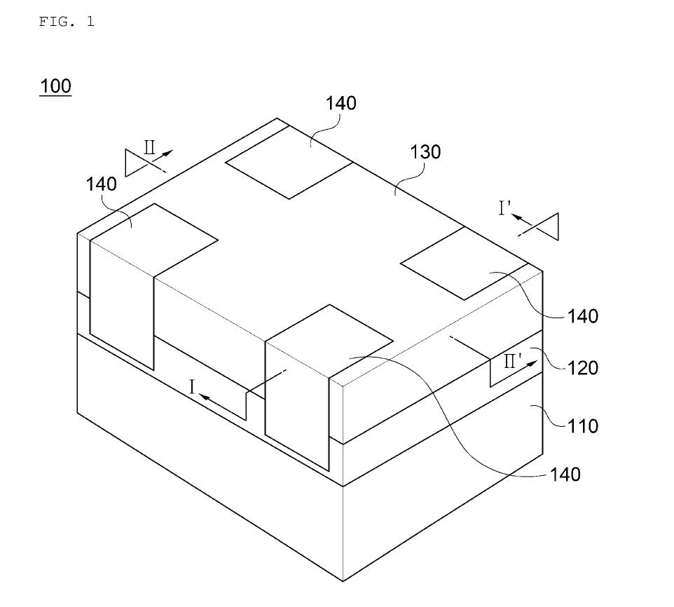

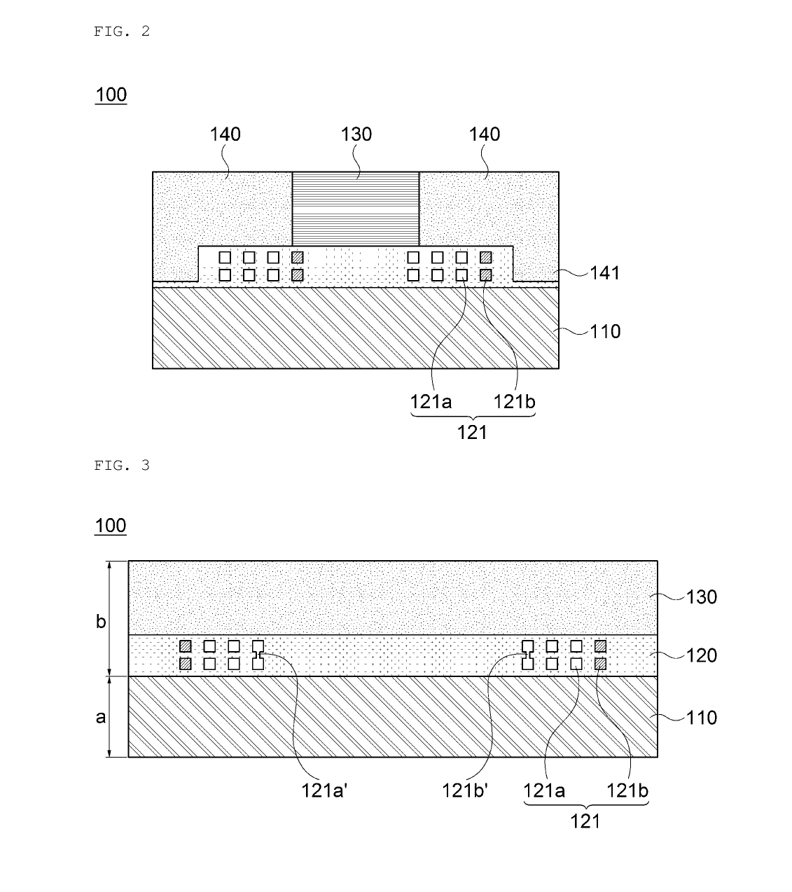

FIG. 1 is a perspective diagram of a common mode filter according to an exemplary embodiment of the present disclosure, FIG. 2 is a cross-sectional diagram taken along line I-I′ of FIG. 1, FIG. 3 is a cross-sectional diagram taken along line II-II′ of FIG. 1, and FIG. 4 is a plan diagram of a layer provided with a coil pattern according to the present disclosure.

Referring to FIGS. 1 to 4, a common mode filter 100 according to the present disclosure includes a support substrate 110, an insulation layer 120 formed on the support substrate 110, and a non-magnetic dielectric body 130 formed on the insulation layer 120.

The support substrate 110 is manufactured in an approximately rectangular parallelepiped shape and disposed at the lowermost portion to support the insulation layer 120 and the non-magnetic dielectric body 130.

The support substrate 110 serves as a path through which a magnetic flux generated in a coil at the time of applying current passes in addition to a supporter. That is, the support substrate 110 may be made of any magnetic material as long as predetermined inductance may be obtained. For example, the support substrate 110 may be made of a Ni-based ferrite material including Fe₂O₃ and NiO as main ingredients, a Ni—Zn-based ferrite material including Fe₂O₃, NiO, and ZnO as main ingredients, a Ni—Zn—Cu-based ferrite material including Fe₂O₃, NiO, ZnO, and CuO as main ingredients, or the like. Further, mechanical strength may be strengthened by sintering these materials at a high temperature.

The insulation layer 120 is formed on the support substrate 110, and a coil pattern 121 is provided in the insulation layer 120. That is, the insulation layer 120, which is a polymer resin layer enclosing the coil pattern 121, serves to secure insulation between patterns of the coil pattern 121 and protect the coil pattern 121 from an external environment.

Therefore, the insulation layer 120 may be made of a polymer resin having excellent insulation, heat resistance, and moisture resistance, or the like. For example, as an optimal material configuring the insulation layer 120, an epoxy resin, a phenol resin, a urethane resin, a silicone resin, a polyimide resin, or the like, may be used.

The coil pattern 121, which is a metal wire plated on a plane in a coil shape, may be made of at least one metal selected from the group consisting of silver (Ag), palladium (Pd), aluminum (Al), nickel (Ni), titanium (Ti), gold (Au), copper (Cu), and platinum (Pt), which have excellent electric conductivity.

The coil pattern 121 is composed of a primary coil pattern 121a and a secondary coil pattern 121b that are electromagnetically coupled to each other. For reference, the primary coil pattern 121a and the second coil pattern 121b are made of the same metal, but in order to provide clear explanation of the present disclosure, the primary coil pattern 121a and the second coil pattern 121b are distinguished and illustrated in the drawings.

The primary coil pattern 121a and the second coil pattern 121b have a dual coil structure in which each of the patterns is alternately disposed, and the primary coil pattern 121a and the secondary coil pattern 121b are simultaneously provided on the same plane as illustrated in drawings. Of course, unlike this, the primary coil pattern 121a and the secondary coil pattern 121b may be disposed on upper and lower layers so as to face each other with a predetermined interval to thereby be electromagnetically coupled to each other.

Further, the primary coil pattern 121a and the secondary coil pattern 121b may be composed of a plurality of layers, and the primary coil pattern 121a on each of the layers may be connected to each other through a via 121a′, and the secondary coil pattern 121b′ on each of the layers may be connected to each other through a via 121b′. For example, as illustrated in the drawings, in the case in which the primary coil pattern 121a and the secondary coil pattern 121b are disposed in the dual coil structure on each of the upper and lower layers, an end portion of a central portion of the primary coil pattern 121a on the upper layer and an end portion of a central portion the primary coil pattern 121a on the lower layer are connected to each other through the via 121a′ to form a primary coil, and similarly, and an end portion of a central portion of the secondary coil pattern 121b on the upper layer and an end portion of a central portion the secondary coil pattern 121b on the lower layer are connected to each other through the via 121b′ to form a secondary coil.

As described above, when current is applied to the primary coil pattern 121a and the secondary coil pattern 121b electromagnetically coupled to each other in the same direction, magnetic fluxes are reinforced with each other, such that common mode impedance is increased, thereby suppressing common mode noise, and when the current flows thereto in directions opposite to each other, the magnetic fluxes are attenuated by each other, such that differential mode impedance is decreased, thereby acting as a noise filter passing only the desired transmission signals.

The non-magnetic dielectric body 130 is disposed so as to be overlapped with a region of the insulation layer 120 in which the coil pattern 121 is formed. Therefore, all of the magnetic fluxes generated in the coil pattern 121 pass through the non-magnetic dielectric body 130.

More specifically, an outside portion of an upper portion of the insulation layer 120 is provided with external terminals 140 having a predetermined thickness, and the non-magnetic dielectric body 130 is inserted into an empty space between the external terminals 140.

The external terminal 140 is electrically connected to the coil pattern 121 through a post electrode 141 extended toward the insulation layer 120. Here, the external terminal 140 may be composed of a first external terminal 140 connected to one end of the primary coil pattern 121a, a second external terminal 140 connected to the other end of the primary coil pattern 121a, a third external terminal 140 connected to one end of the secondary coil pattern 121b, and a fourth external terminal 140 connected to the other end of the secondary coil pattern 121b. The first to fourth external terminals 140 are disposed at four corner portion of the upper portion of the insulation layer 120, respectively, and the non-magnetic dielectric body 130 may be formed so as to fill in an empty space between the first to fourth external terminals 140.

The non-magnetic dielectric body 130 may be made of the same polymer resin as that of the insulation layer 120. Therefore, the non-magnetic dielectric body 130 may be made of any one selected from the group consisting of an epoxy resin, a phenol resin, a urethane resin, a silicone resin, and a polyimide resin, or a mixture thereof. Here, for convenience of manufacturing, it is preferable that the polymer resin configuring the non-magnetic dielectric body 130 is the same as the polymer resin configuring the insulation layer 120.

As the non-magnetic dielectric body 130 is made of the polymer resin as described above, even though the magnetic flux of the coil pattern 121 passes through the non-magnetic dielectric body 130 at a high frequency band, a decrease in magnetic permeability and a magnetic loss are not generated, such that attenuation is improved.

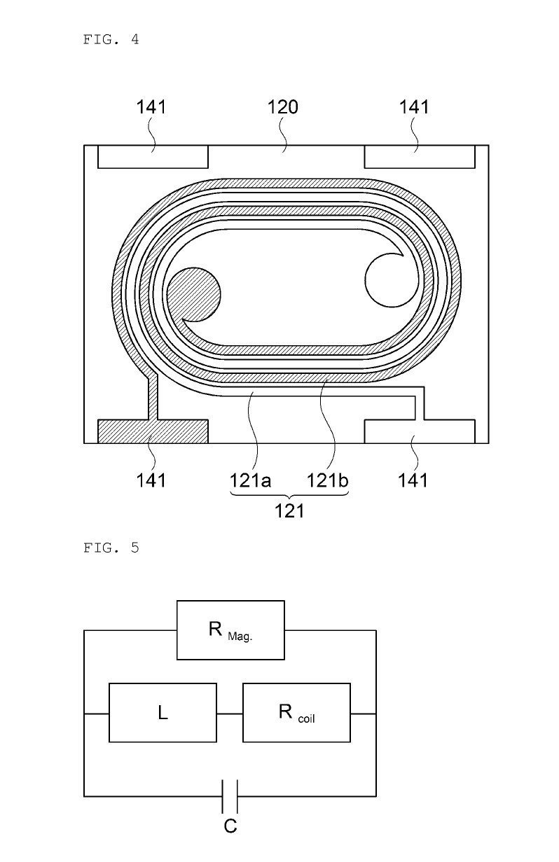

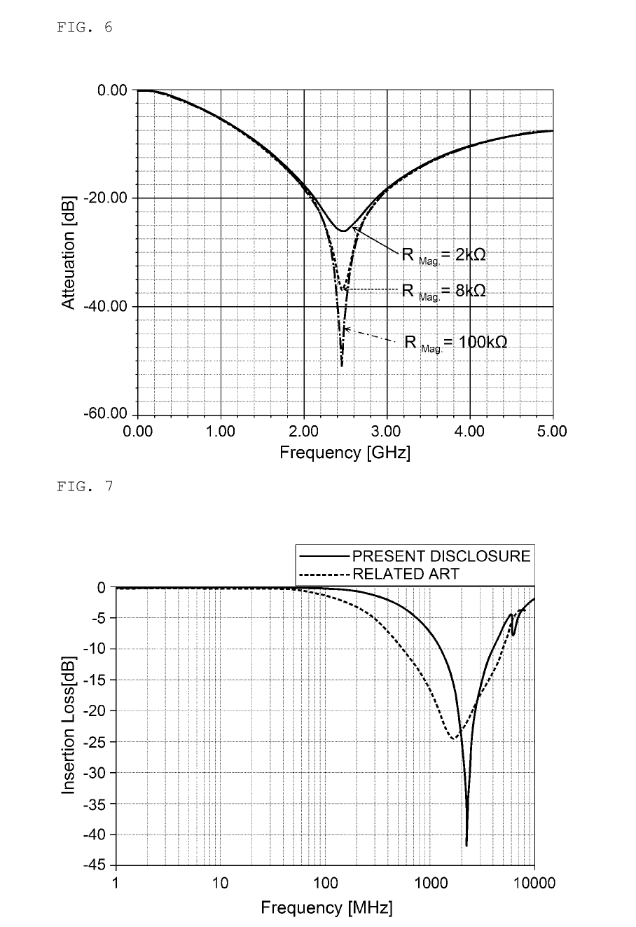

FIG. 5 is an equivalent circuit diagram of a common mode filter according to the related art, including a resistor, and FIG. 6 is a graph illustrating frequency-dependent attenuation of the common mode filter according to the related art. In FIG. 5, L means inductance, R means resistance, and C means capacitance between coil conductors, and resistance R is divided into resistance R_{mag.} by a magnetic material and resistance R_{coil} by the coil conductor.

Since resistance R_{mag.} means a degree of change in electric resistance when a magnetic field is applied, the higher resistance R_{mag.}, the smaller the magnetic loss. On the contrary, the lower resistance R_{mag.}, the larger the magnetic loss. As a result, when resistance R_{mag.} is low, attenuation is deteriorated, such that attenuation becomes −25 dB at the same frequency, but when resistance R_{mag.} is high, attenuation is improved, such that attenuation becomes −49 dB, as illustrated in FIG. 5. Therefore, in the case in which the non-magnetic dielectric body 130 is provided instead of a magnetic body as in the present disclosure, the magnetic loss may be removed, such that attenuation may be significantly improved.

FIG. 7 is a graph for comparing attenuation of the common mode filter according to the present disclosure and attenuation of the common mode filter according to the related art with each other. Here, a horizontal axis indicates a frequency, and a vertical axis indicates an insertion loss. Here, as the common mode filter according to the related art, a common mode filter including a magnetic body instead of the non-magnetic dielectric body 130 was used.

Referring to FIG. 7, it may be appreciated that in the common mode filter according to the present disclosure, since an inductance value was decreased due to the non-magnetic dielectric body 130 that does not have magnetic permeability, a notch frequency was increased (to approximately 2.4 Ghz) as compared to the common mode filter according to the related art, and there was no magnetic loss, such that attenuation was improved.

Here, as another exemplary embodiment of the present disclosure, the support substrate 110 may be made of a non-magnetic material, for example, alumina, silica, or titanium oxide instead of the ferrite material. In this case, there is no magnetic loss by the support substrate 110, such that attenuation may be further improved.

Meanwhile, the common mode filter 100 according to the present disclosure may be configured so that a ratio of a sum (b) of a thickness of the insulation layer 120 and a thickness of the non-magnetic dielectric body 130 to a thickness (a) of the support substrate 110 is 0.23 or more.

A coefficient of thermal expansion of the support substrate 110 is about 10 ppm/K, which is significantly small as compared to the insulation layer 120 or the non-magnetic dielectric body 130 made of the resin composition (generally, the coefficient of thermal expansion of the insulation layer 120 or the non-magnetic dielectric body 130 is in a range of 50 to 80 ppm/K). Stress is generated in an interface between the support substrate 110 and the insulation layer 120 during a reflow process for mounting a chip or a manufacturing process, due to a change in temperature caused by a difference in the coefficient of thermal expansion as described above, and in the case in which the thicknesses of the insulation layer 120 and the non-magnetic dielectric body 130 are thin, cracks are generated in the interface, which cause a defect.

As a result obtained by manufacturing common mode filters while changing the ratio of the sum (b) of the thickness of the insulation layer 120 and the thickness of the non-magnetic dielectric body 130 to the thickness of the support substrate 110 as illustrated in the following Table 1 and observing presence or absence of a defect, it was confirmed that when an R value (here, R is b/a) was less than 0.23, a crack defect was generated.

TABLE 1

| | Presence or Absence of Defect after PCB Mounting |
|---|---|
| R = b/a | Test |
| 0.11 | ◯ |
| 0.15 | ◯ |
| 0.18 | ◯ |
| 0.2 | ◯ |
| 0.23 | X |
| 0.3 | X |
| 0.36 | X |
| 0.43 | X |
| 0.5 | X |
| 0.58 | X |
| 0.88 | X |
| 1.14 | X |

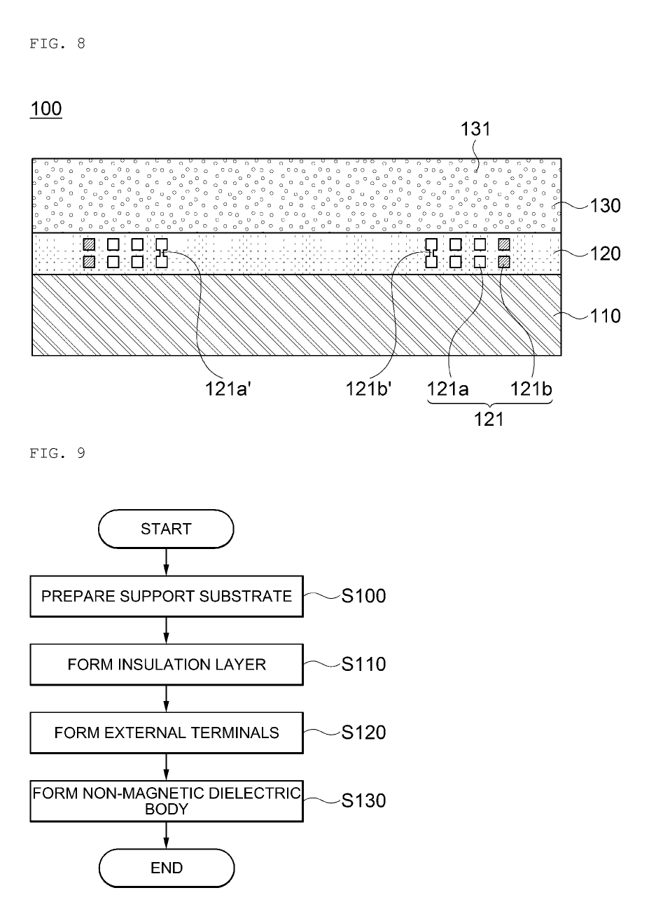

FIG. 8 is a cross-sectional diagram of a common mode filter according to another exemplary embodiment of the present disclosure. According to the present disclosure, a non-magnetic insulation body 130 in which a non-magnetic filler 131 is dispersed may be used as another structure for decreasing the above-mentioned difference in the coefficient of thermal expansion.

As the non-magnetic filler 131, any one selected from the group consisting of alumina (Al₂O₃), silica (SiO₂) and titanium oxide (TiO₂), or a mixture thereof may be used, and coefficients of thermal expansion thereof are approximately 30 to 40 ppm/K, which is small, such that a coefficient of thermal expansion of the non-magnetic insulation body 130 may be decreased. As a result, a deviation of the coefficient of thermal expansion between the non-magnetic insulation body and the support substrate 110 is decreased, such that defects such as cracks caused by stress, and the like, may be prevented.

Hereinafter, a method of manufacturing a common mode filter according to the present disclosure will be described.

FIG. 9 is a flow chart sequentially illustrating the method of manufacturing a common mode filter according to the present disclosure. As a first step of manufacturing a common mode filter according to the present disclosure, first, a support substrate 110 made of a magnetic material such as Ni-based ferrite, Ni—ZN-based ferrite, Ni—Zn—Cu-based ferrite, or the like, or a non-magnetic material such as alumina, silica, titanium oxide, or the like, is prepared (S100).

Then, an insulation layer 120 in which a coil pattern 121 is formed is formed on the support substrate 110 (S110).

In detail, after a process of applying an insulation resin on the support substrate 110 in order to secure insulation, a plating process for forming the coil pattern 121 thereon and a process of applying the insulation resin so as to cover the coil pattern 121 are repeatedly performed. As a plating process, a general semi-additive process, a modified semi-additive process (MSAP), or a subtractive process, or the like, that is known in the art may be used. At this time, post electrodes 141 for connection with external terminals 140 are formed together with the coil pattern 121.

When the insulation layer 120 is formed, a non-magnetic dielectric body 130 is formed thereon, thereby completing the common mode filter according to the present disclosure.

To this end, first, first to fourth external terminals 140 having a predetermined thickness are formed at four corner portion of an upper portion of the insulation layer 120, respectively, by a plating process (S120), and the non-magnetic dielectric body 130 is formed by filling a non-magnetic paste in an empty space between the first to fourth external terminals 140 (S130).

The non-magnetic paste is a non-magnetic material in a liquid phase in which a polymer resin such as epoxy, silicone, polyimide, or the like, and a curing agent are dissolved by a solvent, and the solvent is removed during a drying process after filling and the polymer resin is cured by a subsequent heat-treatment process, thereby forming the non-magnetic dielectric body 130. Here, as the polymer resin contained in a composition of the non-magnetic paste, the same material as the polymer resin configuring the insulation layer is used, which is advantageous in view of cost and production efficiency.

As set forth above, with the common mode noise filter according to the present disclosure, there is no magnetic loss at a high frequency band, such that attenuation may be increased, and accordingly, common mode noise may be effectively suppressed.

The detailed description described above is provided only to illustrate the present disclosure. Although the above-mentioned description is to indicate and describe exemplary embodiments of the present disclosure, the present disclosure may be also used in various other combinations, modifications, and environments. In other words, the present disclosure may be changed or modified within the range of concept of the disclosure disclosed in the specification, the range equivalent to the disclosure and/or the range of the technology or knowledge in the field to which the present disclosure pertains. The exemplary embodiments described above have been provided to explain the best state in carrying out the present disclosure. Therefore, they may be carried out in other states known to the field to which the present disclosure pertains in using other disclosures such as the present disclosure and also be modified in various forms required in specific application fields and usages of the disclosure. Therefore, it is to be understood that the disclosure is not limited to the disclosed embodiments. It is to be understood that other exemplary embodiments are also included within the spirit and scope of the appended claims.

What is claimed is:

1. A common mode filter comprising:
a support substrate;
an insulation layer provided on the support substrate and including a coil pattern formed therein; and
a non-magnetic dielectric body provided on the insulation layer.

2. The common mode filter according to claim 1, wherein a ratio of a sum of a thickness of the insulation layer and a thickness of the non-magnetic dielectric body to a thickness of the support substrate is 0.23 or more.

3. The common mode filter according to claim 1, wherein the non-magnetic dielectric body contains a non-magnetic filler.

4. The common mode filter according to claim 3, wherein the non-magnetic filler is any one selected from the group consisting of alumina (Al₂O₃), silica (SiO₂) and titanium oxide (TiO₂), or a mixture thereof.

5. The common mode filter according to claim 1, further comprising external terminals provided at an outside portion of an upper portion of the insulation layer,
wherein the non-magnetic dielectric body is inserted into an empty spaced between the external terminals.

6. The common mode filter according to claim 1, wherein the non-magnetic dielectric body is made of the same material as that of the insulation layer.

7. The common mode filter according to claim 1, wherein the non-magnetic dielectric body is made of any one selected from the group consisting of an epoxy resin, a phenol resin, a urethane resin, a silicone resin, and a polyimide resin, or a mixture thereof.

8. The common mode filter according to claim 1, wherein the support substrate is made of a magnetic or non-magnetic material.

9. The common mode filter according to claim 1, wherein the coil pattern is composed of a primary coil pattern and a secondary coil pattern electromagnetically coupled to each other.

10. The common mode filter according to claim 9, wherein the primary and secondary coil patterns are alternately disposed on the same plane.

11. The common mode filter according to claim 9, wherein the primary and secondary coil patterns are composed of a plurality of layers, and the same coil pattern on each layer is connected to each other through a via.

12. The common mode filter according to claim 9, further comprising first to fourth external terminals provided at four corner portions of an upper portion of the insulation layer, respectively,
wherein the first to fourth external terminals are connected to one end and the other end of the primary coil pattern and one end and the other end of the secondary coil pattern through post electrodes, respectively, and the non-magnetic dielectric body is inserted into an empty space between the first to fourth external terminals.

13. A method of manufacturing a common mode filter, the method comprising:
preparing a support substrate;
forming an insulation layer in which a coil pattern is formed on the support substrate; and
forming a non-magnetic dielectric body on the insulation layer.

14. The method according to claim 13, wherein the forming of the non-magnetic dielectric body is performed by forming first to fourth external terminals at four corner portions of an upper portion of the insulation layer, respectively, and then filling a non-magnetic paste in an empty space between the first to fourth external terminals.

15. The method according to claim 14, wherein a composition of the non-magnetic paste contains the same material as a polymer resin configuring the insulation layer.
